(19) United States
(12) Patent Application Publication
(10) Pub. No.: US 2009/0266587 A1
(43) Pub. Date: Oct. 29, 2009

(54) FLEXIBLE PRINTED CIRCUIT BOARD AND METHOD OF FORMING FINE PITCH THEREIN

(75) Inventors: Chong-han Park, Changwon-city (KR); Byoung-woo Kim, Changwon-city (KR)

Correspondence Address: DRINKER BIDDLE & REATH LLP;ATTN: PATENT DOCKET DEPT., 191 N. WACKER DRIVE, SUITE 3700, CHICAGO, IL, 60606, US

(73) Assignee: Samsung Techwin Co., Ltd., Changwon-city (KR)

(21) Appl. No.: 12/423,958

(22) Filed: Apr. 15, 2009

(30) Foreign Application Priority Data
Apr. 25, 2008 (KR) 10-2008-0038952

(51) Int. Cl. H05K 1/00; C23F 1/00

(52) U.S. Cl. 174/254; 216/18

(57) ABSTRACT

Provided is a method of forming a fine pitch in a flexible printed circuit board (FPCB) having an increased adhesive property of wirings and an improved insulating property between the wirings. The method includes etching regions where wirings are to be formed on a base substrate; forming conductive layers on the etched regions; forming a photoresist film on a substrate between the etched regions; forming the wirings by forming the conductive layers on the etched regions to be higher than the substrate; and removing the photoresist film.

### CROSS-REFERENCE TO RELATED PATENT APPLICATION

This application claims the benefit of Korean Patent Application No. 10-2008-0038952, filed on Apr. 25, 2008, in the Korean Intellectual Property Office, the disclosure of which is incorporated herein in its entirety by reference.

### BACKGROUND OF THE INVENTION

1. Field of the Invention

The present invention relates to a flexible printed circuit board (FPCB) on which a semiconductor package or an integrated circuit chip is mounted, and more particularly, to a method of forming a fine pitch in a FPCB.

2. Description of the Related Art

In general, conventional printed circuit boards (PCBs) are rigid products used for mechanically supporting and electrically connecting electronic components such as semiconductor packages or integrated circuit chips in various electronic products. However, as the electronic products are manufactured to have smaller sizes and more functions, flexible printed circuit boards (FPCBs), which can be installed in a small place and can accommodate thereon many electronic components, are widely used.

Flexible printed circuit boards (FPCBs) include electric circuits having various patterns in order to mount thereon many electronic components. Thus, in order to increase the integration of the electronic components, a fine pitch should be realized in FPCBs.

Conventionally, there are two methods of realizing a fine pitch in an FPCB. First, in order to form a terminal having a predetermined thickness in a FPCB, a copper layer is formed to a predetermined thickness in the FPCB, and then the copper layer is etched. Second, a thin copper seed is formed in a FPCB, and then a copper layer is formed in the copper seed by using an electroplating method.

However, when wirings are formed using such conventional methods of forming a fine pitch, an adhesive property of the wirings can be decreased and an insulating property between wirings can be deteriorated. Thus, there is a need for new FPCB and a method of manufacturing the same that can address the above problems.

### SUMMARY OF THE INVENTION

The present invention provides a method of forming a fine pitch in a flexible printed circuit board (FPCB) having an increased adhesive property of wirings and an improved insulating property between the wirings.

The present invention also provides a FPCB manufactured by the above method.

According to an aspect of the present invention, there is provided a method of forming a fine pitch in a flexible printed circuit board (FPCB), the method including: etching regions where wirings are to be formed on a base substrate; forming conductive layers on the etched regions; forming a photoresist film on a substrate between the etched regions; forming the wirings by forming the conductive layers on the etched regions to be higher than the substrate; and removing the photoresist film.

According to another aspect of the present invention, there is provided a FPCB manufactured by a method including: etching regions where wirings are to be formed on a base substrate; forming conductive layers on the etched regions; forming a photoresist film on a substrate between the etched regions; forming the wirings by forming the conductive layers on the etched regions to be higher than the substrate; and removing the photoresist film.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic view illustrating a method of manufacturing a FPCB according to an embodiment of the present invention;

FIG. 2 is a cross-sectional view of a base substrate before a FPCB is completed, according to an embodiment of the present invention;

FIG. 3 is a cross-sectional view of the base substrate on which a first photoresist film is formed, according to an embodiment of the present invention;

FIG. 4 is a cross-sectional view of the base substrate undergoing a first masking process, according to an embodiment of the present invention;

FIG. 5 is a cross-sectional view of the base substrate undergoing a first exposure process, according to an embodiment of the present invention;

FIG. 6 is a cross-sectional view of the base substrate from which a first mask is removed, according to an embodiment of the present invention;

FIG. 7 is a cross-sectional view of the base substrate undergoing an etching process, according to an embodiment of the present invention;

FIG. 8 is a cross-sectional view of the base substrate from which all the first photoresist film is removed, according to an embodiment of the present invention;

FIG. 9 is a cross-sectional view of the base substrate on which a first conductive layer is formed, according to an embodiment of the present invention;

FIG. 10 is a cross-sectional view of the base substrate on which a second photoresist film is formed on the first conductive layer, according to an embodiment of the present invention;

FIG. 11 is a cross-sectional view of the base substrate undergoing a second masking process, according to an embodiment of the present invention;

FIG. 12 is a cross-sectional view of the base substrate undergoing a second exposure process, according to an embodiment of the present invention;

FIG. 13 is a cross-sectional view of the base substrate from which a second mask is removed, according to an embodiment of the present invention;

FIG. 14 is a cross-sectional view of the base substrate on which a second conductive layer is formed in an area where the second photoresist film is removed, according to an embodiment of the present invention;

FIG. 15 is a cross-sectional view of the base substrate from which the second photoresist film is removed, according to an embodiment of the present invention; and

FIG. 16 is a cross-sectional view of a completed FPCB of which wirings are capped, according to an embodiment of the present invention.

### DETAILED DESCRIPTION OF THE INVENTION

Hereinafter, the present invention will be described in detail by explaining exemplary embodiments of the invention with reference to the attached drawings. The same reference numerals in the drawings denote the same element.

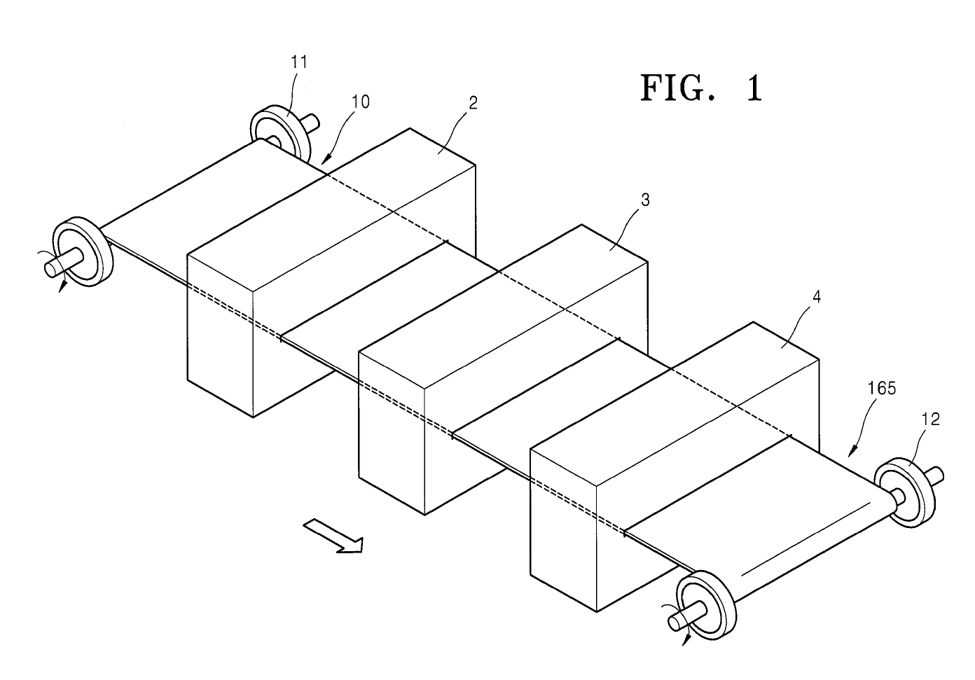

FIG. 1 is a schematic view illustrating a method of manufacturing a FPCB 165 according to an embodiment of the present invention. The FPCB 10 illustrated in FIG. 1 may be manufactured by a roll-to-roll method or a sheet method.

Referring to FIG. 1, a base substrate 10, that is, a raw material in which an circuit pattern has not been formed, is unwound from a supplying roll 11 and wound up on a recovering roll 12, is unwound from the supplying roll 11 while passing simultaneously through an exposure apparatus 2, an etching apparatus 3, and a deposition apparatus 4 for manufacturing the FPCB 165. Then, the FPCB 165 is wound up on the recovering roll 12.

In order to manufacture the FPCB 165, the exposure apparatus 2, the etching apparatus 3, and the deposition apparatus 4 are sequentially arranged in a moving direction of the base substrate from the supplying roll 11 to the recovering roll 12. For example, the exposure apparatus 2, the etching apparatus 3, and the deposition apparatus 4 are sequentially arranged in an arrow direction as shown in FIG. 1.

The exposure apparatus 2, the etching apparatus 3, and the deposition apparatus 4 of FIG. 1 are schematically illustrated to describe a method of manufacturing the FPCB according to an embodiment of the present invention. However, the present invention is not limited thereto, and other various apparatuses may be arranged in various forms.

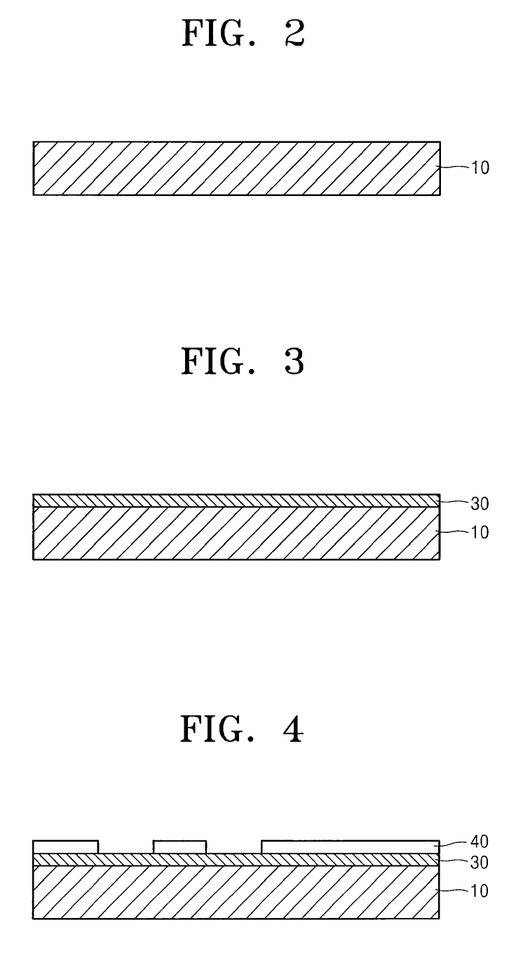

FIGS. 2 through 16 are cross-sectional views for explaining a method of manufacturing a FPCB 165 of FIG. 16, according to an embodiment of the present invention.

FIG. 2 is a cross-sectional view of the base substrate 10 before the FPCB 165 is manufactured, according to an embodiment of the present invention. Referring to FIG. 2, the base substrate 10 is made of an insulating material, such as a polyimide film or a polyester film. That is, the inside of the base substrate 10 may be formed of a composition of glass fiber and resin. The base substrate 10 may be manufactured to a predetermined thickness, for example, less than 0.15 mm so as to be flexible. Thus, the base substrate 10 can be wound up on the supplying roll 11 and the recovering roll 12 as illustrated in FIG. 1.

FIG. 3 is a cross-sectional view of the base substrate 10 on which a first photoresist film 30 is formed, according to an embodiment of the present invention. Referring to FIG. 3, a photoresist is coated on the entire surface of the base substrate 10, thereby forming the first photoresist film 30. The first photoresist film 30 may be formed of dry film resist (DFR), and may be also formed of a photosensitive film or ink. In order to sufficiently adhere the first photoresist film 30 to the base substrate 10, the first photoresist film 30 may be formed after heating the surface of the base substrate 10.

FIG. 4 is a cross-sectional view of the base substrate 10 undergoing a first masking process, according to an embodiment of the present invention. Referring to FIG. 4, the entire surface of the base substrate 10 is covered by a first mask 40 having a predetermined pattern. An operation for covering the entire surface of the base substrate 10 with the first mask 40 having a predetermined pattern is referred to as masking. The surface of the base substrate 10 is divided into a region where a wiring is to be formed, that is, a region which is to be etched to form the wiring, and a region where a wiring is not to be formed. Accordingly, the first mask 40 is not placed on the region where the wiring is to be formed, and is placed only on the region where the wiring is not to be formed, that is, a region which is not to be etched. The first mask 40 may be adhered to the base substrate 10 as illustrated in FIG. 4, and may be formed in a free state on the base substrate 10 without being adhered to the base substrate 10. The first mask 40 may be made of a removable film, a photosensitive resin, or a dry film.

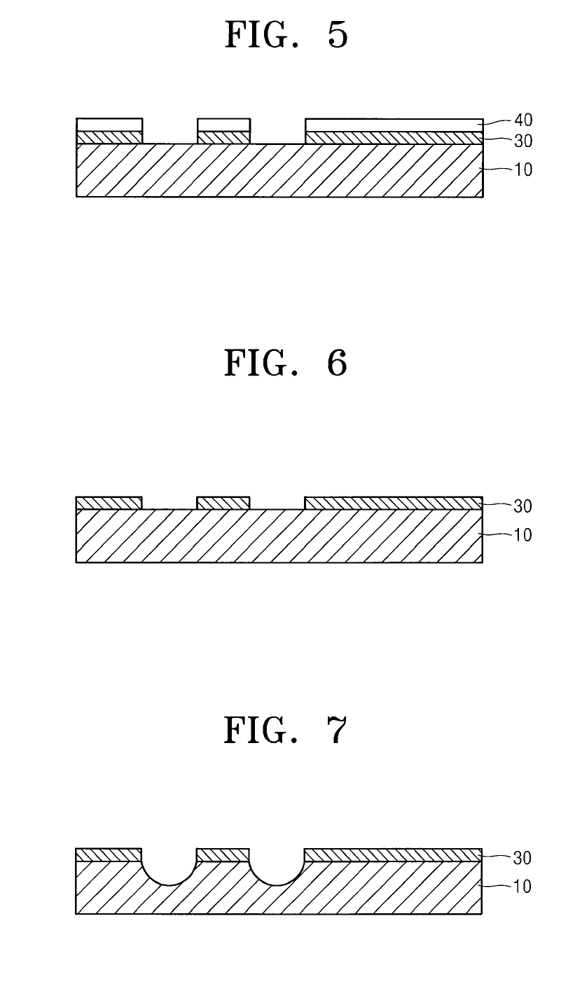

FIG. 5 is a cross-sectional view of the base substrate 10 undergoing a first exposure process, according to an embodiment of the present invention. Referring to FIG. 5, when the base substrate 10 on which masking is performed enters the exposure apparatus 2 of FIG. 1, light, such as ultra-violet (UV) light, is irradiated to the base substrate 10. Accordingly, the first photoresist film 30 in the region where the first mask 40 is not formed is removed, and the first photoresist film 30 in the region where the first mask 40 is formed is maintained as it is. A developing process may be additionally performed after performing the exposure process according to the type of the first photoresist film 30, in order to remove the first photoresist film 30.

FIG. 6 is a cross-sectional view of the base substrate 10 from which the first mask 40 is removed, according to an embodiment of the present invention. Referring to FIG. 6, the first mask 40 is removed after removing the first photoresist film 30 in the region where the first mask 40 is formed after the exposure process is finished. When the first mask 40 is adhered to the base substrate 10, the first mask 40 is removed by stripping or using an etching material.

FIG. 7 is a cross-sectional view of the base substrate 10 undergoing the etching process, according to an embodiment of the present invention. Referring to FIG. 7, when the base substrate 10 enters the etching apparatus 3 of FIG. 1, an etching material is sputtered from an upper portion of the etching apparatus 3 on the base substrate 10. Thus, the region of the base substrate 10 where the first photoresist film 30 is not formed is etched to a predetermined thickness, and the region where the first photoresist film 30 is formed is maintained as it is.

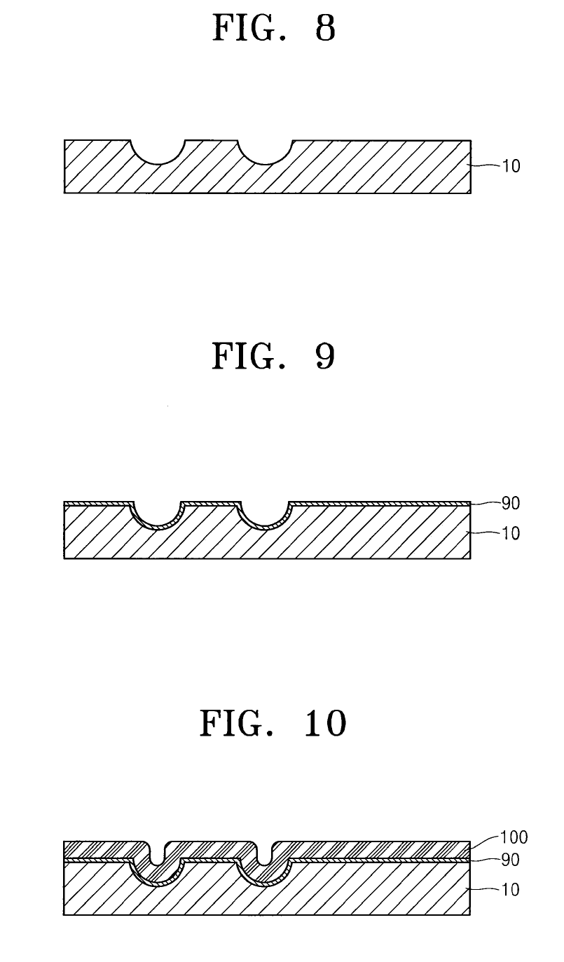

FIG. 8 is a cross-sectional view of the base substrate 10 from which all the first photoresist film 30 is removed, according to an embodiment of the present invention. Referring to FIG. 8, when the base substrate 10 enters the etching apparatus 3, an exfoliating material is sputtered on the base substrate 10 to exfoliate the first photoresist film 30.

FIG. 9 is a cross-sectional view of the base substrate 10 on which a first conductive layer 90 is formed, according to an embodiment of the present invention. Referring to FIG. 9, when the base substrate 10 enters the deposition apparatus 4 of FIG. 1, the deposition apparatus 4 deposits a material having electroconductivity, such as copper, nickel chrome, or an copper-nickel chrome alloy, on the base substrate 10 to form the conductive layer 90. The conductive layer 90 may be formed to be thin.

FIG. 10 is a cross-sectional view of the base substrate 10 when a second photoresist film 100 is formed on the first conductive layer 90, according to an embodiment of the present invention. Referring to FIG. 10, the second photoresist film 100, for example, dry film resist (DFR), is formed to a predetermined thickness on the entire surface of the conductive layer 90. The predetermined thickness may be equal to that of a wiring to be formed on the base substrate 10. The second photoresist film 100 may be formed by vapor deposition.

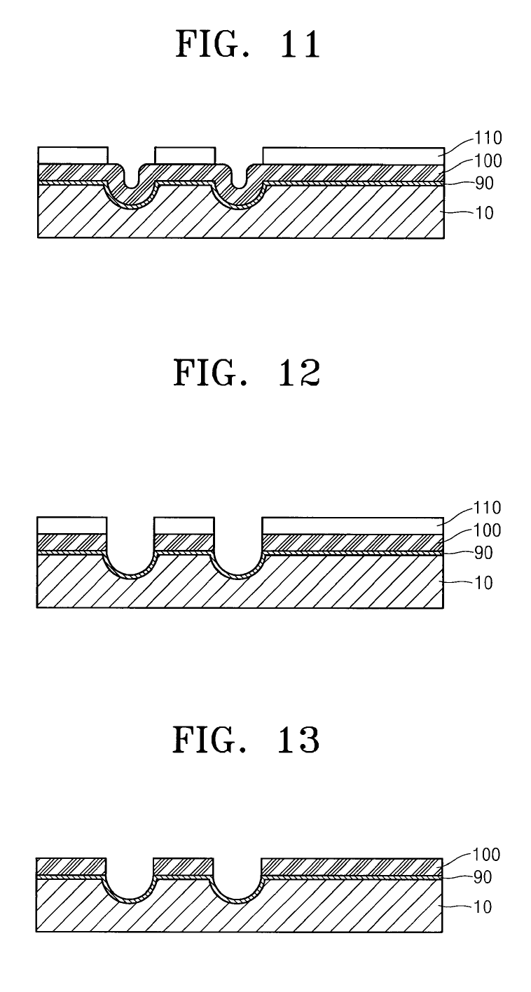

FIG. 11 is a cross-sectional view of the base substrate 10 undergoing a second masking process, according to an embodiment of the present invention. Referring to FIG. 11, the second photoresist film 100 is divided into a region to be etched and a region not to be etched, and the region not to be etched is covered by a second mask 110. The second mask 110 may be adhered to the base substrate 10 as illustrated in FIG. 11, and may be formed in a free state on the base substrate 10 without being adhered to the base substrate 10. The second mask 110 may be made of a removable film, a photosensitive resin, or a dry film.

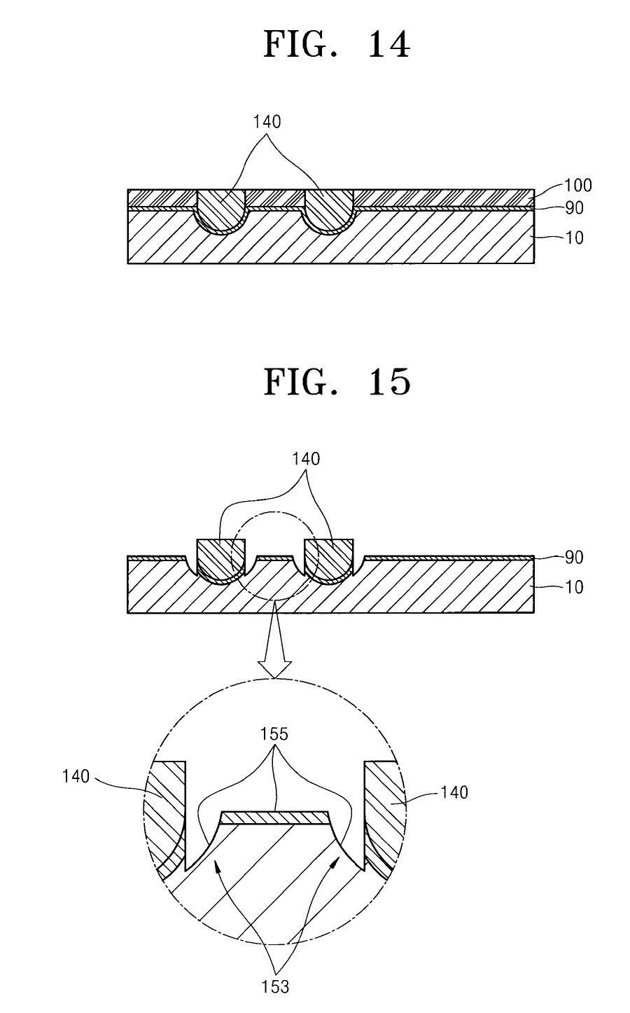

FIG. 12 is a cross-sectional view of the base substrate 10 undergoing a second exposure process, according to an embodiment of the present invention. Referring to FIG. 12, when the base substrate 10 on which masking is performed enters the exposure apparatus 2 (FIG. 1), the second photoresist film 100 of the region where the second mask 110 is not formed is removed, and the second photoresist film 100 of the region where the second mask 110 is formed is maintained as it is. A developing process may be additionally performed after performing the exposure process according to the type of the second photoresist film 100 in order to remove the second photoresist film 100.

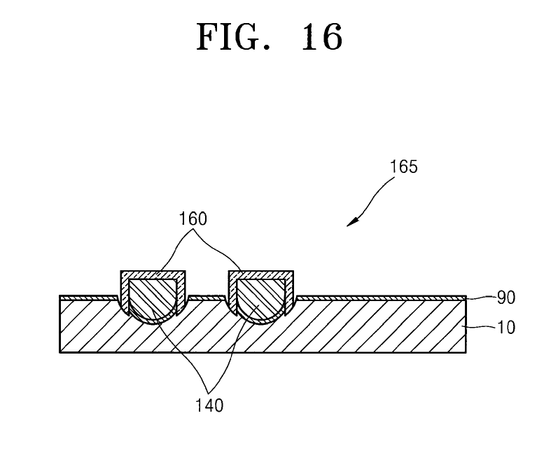

FIG. 13 is a cross-sectional view of the base substrate 10 from which the second mask 110 is removed, according to an embodiment of the present invention. Referring to FIG. 13, after the second exposure process is finished, the second mask 110 of FIG. 12 is removed by stripping or using an etching material. FIG. 14 is a cross-sectional view of the base substrate 10 when wirings 140 are formed on a region where the second photoresist film 100 is removed, according to an embodiment of the present invention. Referring to FIG. 14, the wirings 140 are formed by growing a conductive material, for example, copper, in the region where the second photoresist film 100 is removed, by using an electroplating method. The wirings 140 may be formed to have the same height as the second photoresist film 100 remaining in the base substrate 10. Since the conductive layer 90 is formed of a high adhesive material, the wirings 140 have high adhesive properties so as to be adhered to the base substrate 10 by the conductive layer 90.

FIG. 15 is a cross-sectional view of the base substrate 10 from which the second photoresist film 100 is removed, according to an embodiment of the present invention. Referring to FIG. 15, all the second photoresist film 100 of FIG. 14 remaining in the base substrate 10 is removed by exfoliating using an exfoliating material. Accordingly, only the wirings 140 remain as illustrated in FIG. 15. The wirings 140 electrically connect each of electronic components mounted on the FPCB 165 of FIG. 16. In removing the second photoresist film 100 of FIG. 14, a part of side lower end portions of the wirings 140 is etched, thereby generating an undercut effect as illustrated in FIG. 15. Paths between the wirings 140 are extended due to the undercut effect, thereby increasing an insulating property between the wirings 140.

As such, according to the present invention, an insulating property between the wirings 140 and an adhesive property of the wirings 140 are increased, and thus a fine pitch can be formed.

FIG. 16 is a cross-sectional view of a completed FPCB 165 when the wirings 140 are capped, according to an embodiment of the present invention. Referring to FIG. 16, in order to protect the wirings 140 from external factors, and increase the conductivity of the wirings 140, a capping layer 160 is formed by capping an upper portion and a side portion of the wiring 140 with a conductive material, for example, tin (sn), silver (Au), gold (Ag), lead (Pd) or an alloy thereof.

In order to form the capping layer 160, an additional process may be performed as follows. A third photoresist film is formed on the entire surface of the FPCB 165, and then masking is performed on the third photoresist film. Then, after the third photoresist film formed on the wirings 140 is removed, a conductive material is deposited on the entire surface of the FPCB 165 and the remaining portions of the third photoresist film are removed.

Also, in order to protect the wirings 140 from external factors, a cover layer film or silicon may be additionally partially or entirely coated on the FPCB 165, or the FPCB 165 may be gold-plated in order to increase the corrosion resistance of the FPCB 165.

Also, when the wirings 140 are formed only in an upper portion of the FPCB 165, a stiffener may be adhered to the lower portion of the FPCB 165 in order to prevent the FPCB 165 from bending.

FIGS. 2 through 16 illustrate a case where the wirings 140 are formed only in the upper portion of the FPCB 165. However, the wirings 140 may be also formed in the lower portion of the FPCB 165 using the same method.

The FPCB 165 can be used for electrical connections between a main circuit substrate, such as a cellular phone, a notebook computer, or a liquid crystal display (LCD) image display apparatus, and an LCD module, and for controlling signal transmission.

According to the present invention, undercuts are formed in side lower end portions, so that an insulating property between wirings can be increased. Accordingly, a fine pitch in a FPCB can be formed.

Also, a first conductive layer is formed so as to increase an adhesive property of wirings.

While the present invention has been particularly shown and described with reference to exemplary embodiments thereof, it will be understood by one of ordinary skill in the art that various changes in form and details may be made therein without departing from the spirit and scope of the present invention as defined by the following claims.

What is claimed is:

1. A method of forming a fine pitch in a flexible printed circuit board, the method comprising:
etching regions where wirings are to be formed on a base substrate;
forming conductive layers on the etched regions;
forming a photoresist film on a substrate between the etched regions;
forming the wirings by forming the conductive layers on the etched regions to be higher than the substrate; and
removing the photoresist film.

2. The method of claim 1, wherein the conductive layers are made of nickel chrome having a high adhesive property between the conductive layers and the wirings.

3. The method of claim 1, wherein the photoresist film is formed of a dry film resist.

4. The method of claim 1, wherein the photoresist film is removed by etching using an etching apparatus, and an etching process is performed until an undercut effect occurs, whereby a part of side lower end portions of wirings is removed.

5. The method of claim 1, further comprising capping upper sides of the wirings with a predetermined material after removing the photoresist film.

6. A flexible printed circuit board manufactured by a method comprising:
etching regions where wirings are to be formed on a base substrate;
forming conductive layers on the etched regions;
forming a photoresist film on a substrate between the etched regions;
forming the wirings by forming the conductive layers on the etched regions to be higher than the substrate; and
removing the photoresist film.

7. The flexible printed circuit board of claim 6, wherein semiconductor parts and a part of semiconductor chips are connected to the wirings.

8. The flexible printed circuit board of claim 6, wherein the conductive layers are made of nickel chrome having a high adhesive property between the conductive layers and the wirings.

9. The flexible printed circuit board of claim 6, wherein the photoresist film is formed of a dry film resist (DFR).

10. The flexible printed circuit board of claim 6, wherein the photoresist film is removed by etching using an etching apparatus, and an etching process is performed until an undercut effect occurs, whereby a part of side lower end portions of wirings is removed.

11. The flexible printed circuit board of claim 6, further comprising capping upper sides of the wirings with a predetermined material after removing the photoresist film.

12. A fine pitch flexible printed circuit board, comprising:
a substrate;
a conductive layer adherent to the substrate; and
a plurality of wiring adherent to a region of the conductive layer,
wherein a part of side lower end portions of the plurality of wiring is removed thereby increasing an insulating property of the plurality of wiring.

13. The fine pitch flexible printed circuit board of claim 12, wherein the conductive layer is made of nickel chrome having a high adhesive property between the conductive layer and the plurality of wiring.

14. The fine pitch flexible printed circuit board of claim 12, further comprising capping upper sides of the wirings with a predetermined material.
